(19) United States
(12) Patent Application Publication
(10) Pub. No.: US 2015/0347806 A1
(43) Pub. Date: Dec. 3, 2015

(54) CHIP PACKAGE STRUCTURE AND METHOD FOR MANUFACTURING CHIP PACKAGE STRUCTURE

(71) Applicants: ChipMOS Technologies Inc., Hsinchu (TW); ChipMOS Technologies (Bermuda) Ltd., Hamilton (BM)

(72) Inventors: Li-Chun Li, Hsinchu (TW); Chia-I Tsai, Hsinchu (TW)

(21) Appl. No.: 14/477,870

(22) Filed: Sep. 5, 2014

(30) Foreign Application Priority Data
May 28, 2014 (TW) 103118657

(51) Int. Cl. G06K 9/00; H01L 21/56; H01L 23/31; H01L 21/48; H01L 23/498; H01L 23/00

(52) U.S. Cl. CPC G06K 9/0002; G06K 9/00053; H01L 23/4985; H01L 23/49838; H01L 24/17; H01L 23/3157; H01L 23/49894; H01L 21/4853; H01L 21/4857; H01L 23/49822; H01L 21/563; H01L 24/81; H01L 2224/81203; H01L 2224/16227; H01L 2924/07025; H01L 2924/1579

(57) ABSTRACT

A chip package structure includes a flexible substrate, a patterned circuit layer, a fingerprint sensor chip, a plurality of bumps, a patterned dielectric layer and an encapsulant layer. The patterned circuit layer disposed on the flexible substrate includes a fingerprint sensing circuit and a plurality of terminals. The fingerprint sensor chip disposed on the flexible substrate is electrically connected to the fingerprint sensing circuit and includes an active surface, a back surface, and a plurality of bonding pads disposed on the active surface. The bumps disposed between the fingerprint sensor chip and the patterned circuit layer electrically connect the bonding pads and the terminals. The patterned dielectric layer including a first surface and a second surface having a fingerprint sensing region at least covers the fingerprint sensing circuit with the first surface. The encapsulant layer is filled between the flexible substrate and the fingerprint sensor chip and covers the bumps.

### CROSS-REFERENCE TO RELATED APPLICATION

This application claims the priority benefit of Taiwan application serial no. 103118657, filed on May 28, 2014. The entirety of the above-mentioned patent application is hereby incorporated by reference herein and made a part of this specification.

### BACKGROUND OF THE INVENTION

1. Field of the Invention

The invention is related to a semiconductor package structure and a method for manufacturing a semiconductor package structure, and more particularly to a fingerprint sensor chip package structure and a method for manufacturing a fingerprint sensor chip package structure.

2. Description of Related Art

A fingerprint sensing package structure may be equipped in various electronic products such as a mobile phone, a notebook computer, a tablet for identifying the user's fingerprint. Currently, a fingerprint sensor may be manufactured by using a semiconductor manufacturing process and further packaged; different from a conventional IC package, the fingerprint sensor chip should be provided with an exposed sensing region for sensing the fingerprint.

Generally speaking, a fingerprint sensor package structure mainly includes a substrate, a fingerprint sensor chip and an encapsulant. An active surface of the fingerprint sensor chip is provided with a sensing region, wherein the fingerprint sensor chip is disposed on a surface of the substrate and gold wires, for example, are used to electrically connect the bonding pads of the fingerprint sensor chip to the signal transmitting circuits of the substrate. The encapsulant is formed at a part of the active surface of the fingerprint sensor chip to cover the gold wires; however, the sensing region is exposed and therefore is likely to be damaged due to an impact or be damped. Meanwhile, the encapsulant is made thicker to prevent the gold wires from being exposed, which increases the height difference between the fingerprint sensing region and the encapsulant surface and consequently reduces the sensitivity of fingerprint identification.

### SUMMARY OF THE INVENTION

The invention provides a chip package structure having a patterned dielectric layer covering a fingerprint sensing circuit. The patterned dielectric layer may be thinned and has a more uniform thickness and may enhance the sensitivity of fingerprint identification.

The invention provides a method for manufacturing a chip package structure having a patterned dielectric layer covering the fingerprint sensing circuit, wherein the patterned dielectric layer may be thinned and has a more uniform thickness and may enhance the sensitivity of fingerprint identification.

In the invention, the chip package structure includes a flexible substrate, a patterned circuit layer, a fingerprint sensor chip, a plurality of bumps, a patterned dielectric layer, and an encapsulant layer. The patterned circuit layer is disposed on the flexible substrate and includes a fingerprint sensing circuit and a plurality of terminals. The fingerprint sensor chip is disposed on the flexible substrate and electrically connected to the fingerprint sensing circuit. The fingerprint sensor chip includes an active surface, a back surface and a plurality of bonding pads disposed on the active surface. The bumps are disposed between the fingerprint sensor chip and the patterned circuit layer to be electrically connected to the bonding pads and terminals, respectively. The patterned dielectric layer includes a first surface and a second surface opposite to each other. The patterned dielectric layer at least covers the fingerprint sensing circuit with the first surface. The second surface has a fingerprint sensing region. The encapsulant layer is filled between the flexible substrate and the fingerprint sensor chip and covers the bumps.

In the invention, the method for manufacturing the chip package structure includes the following steps. Firstly, a flexible substrate is provided. Next, a conductive layer is formed on the flexible substrate. Subsequently, a patterning process is performed to the conductive layer to form a patterned circuit layer on the flexible substrate. The patterned circuit layer includes a fingerprint sensing circuit. Thereafter, a dielectric layer is formed on the flexible substrate. The dielectric layer covers the patterned circuit layer. Then, a patterning process is performed to the dielectric layer to form a patterned dielectric layer. The patterned dielectric layer includes a first surface and a second surface opposite to each other. The patterned dielectric layer at least covers the fingerprint sensing circuit with the first surface. The second surface has a fingerprint sensing region. Next, a fingerprint sensor chip is disposed on the flexible substrate and electrically connected to the fingerprint sensing circuit via a plurality of bumps. Thereafter, an encapsulant layer is filled between the flexible substrate and the fingerprint sensor chip and covers the bumps.

In an embodiment of the invention, a thickness of the flexible substrate is greater than a thickness of the patterned dielectric layer.

In an embodiment of the invention, the thickness of the patterned dielectric layer is substantially no more than 10 μm.

In an embodiment of the invention, the thickness of the patterned dielectric layer substantially lies in the range of 4 μm to 8 μm.

In an embodiment of the invention, the chip package structure further includes a seed layer disposed between the flexible substrate and the patterned circuit layer.

In an embodiment of the invention, materials of the patterned dielectric layer and the flexible substrate include polyimide.

In an embodiment of the invention, the encapsulant layer includes an underfill, a non-conductive paste (NCP), a non-conductive film (NCF), an anisotropic conductive paste (ACP) or an anisotropic conductive film (ACF).

In an embodiment of the invention, the step of forming the conductive layer on the flexible substrate further includes forming a seed layer on the flexible substrate, and performing a plating process by using the seed layer as an electrode to form the conductive layer on the flexible substrate.

In an embodiment of the invention, the step of performing a patterning process to the conductive layer further includes performing the patterning process to the conductive layer and the seed layer.

In an embodiment of the invention, the step of performing a patterning process to the dielectric layer includes a photolithography process.

In an embodiment of the invention, the method for disposing the fingerprint sensor chip on the flexible substrate includes a thermocompression bonding method.

In an embodiment of the invention, the step of disposing the fingerprint sensor chip on the flexible substrate includes compression bonding the fingerprint sensor chip to the flexible substrate and applying an ultrasonic vibration during the bonding process.

Based on the above, the invention, for example, uses the photolithography process to form the patterned dielectric layer covering the fingerprint sensing circuit in order to prevent the fingerprint sensing circuit from being damaged or damped. Accordingly, since the thickness of the patterned dielectric layer may be controlled by a photoresist layer, a patterned dielectric layer with thinner and more uniform thickness can be formed; thereby the sensitivity of fingerprint identification can be enhanced.

To make the aforementioned and other features and advantages of the disclosure more comprehensible, several embodiments accompanied with drawings are described in detail as follows.

### BRIEF DESCRIPTION OF THE DRAWINGS

FIGS. 1A-1H are cross-sectional views illustrating a fabrication flow of a chip package structure according to an embodiment of the invention.

### DESCRIPTION OF EMBODIMENTS

It is to be understood that the foregoing and other detailed descriptions, features, and advantages are intended to be described more comprehensively by providing embodiments accompanied with figures hereinafter. In this regard, directional terminology, such as “top,” “bottom,” “front,” “back,” “left,” “right,” etc., is used with reference to the orientation of the Figure(s) being described. As such, the directional terminology is used for purposes of illustration and is in no way limiting. Meanwhile, identical or similar elements are denoted by the same or similar reference numerals in the following embodiments.

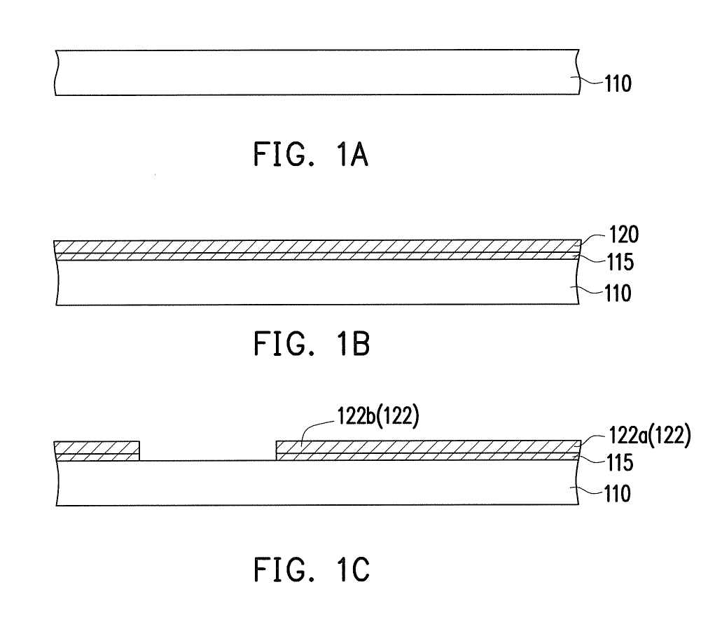

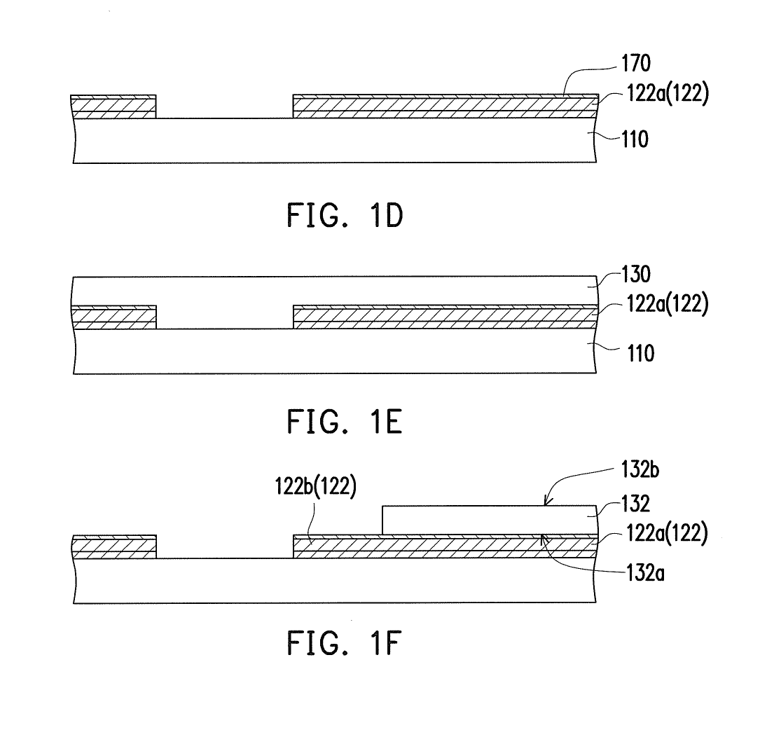

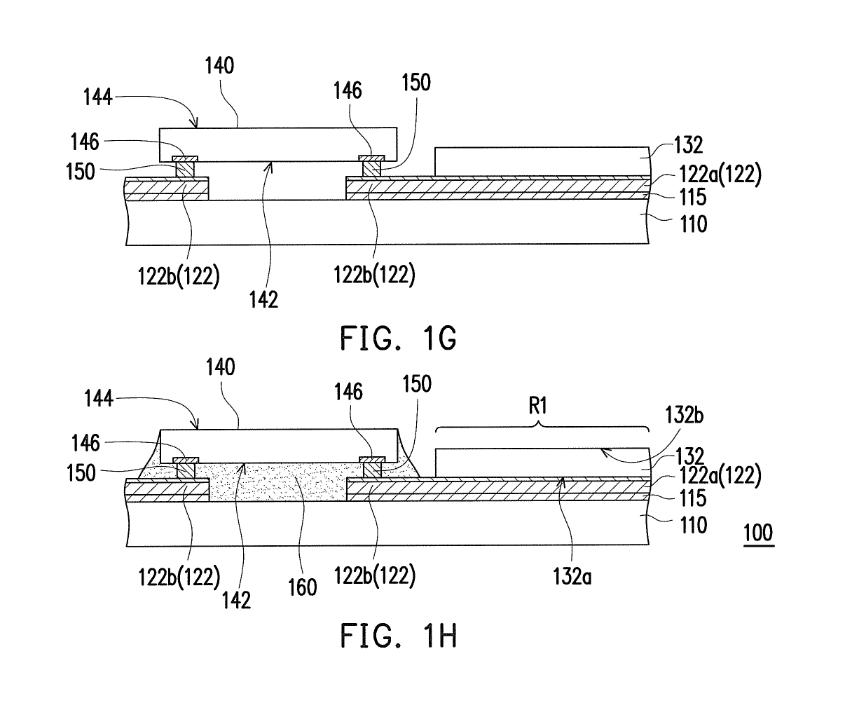

FIGS. 1A-1H are cross-sectional views illustrating a fabrication flow of a chip package structure according to an embodiment of the invention. In the embodiment, a method for manufacturing the chip package structure may include the following steps. Firstly, as shown in FIG. 1A, a flexible substrate 110 is provided. In the embodiment, the flexible substrate 110 may be a chip-on-film (COF) substrate or other flexible substrates that may be formed of polyimide (PI) or other suitable materials. In addition, a thickness of the flexible substrate 110 of the embodiment may be substantially between 25 μm and 38 μm. Certainly, it should be understood by persons of ordinary skill in the art that the embodiment serves as an example only; users may adjust the thickness of the flexible substrate 110 at their discretion depending on the requirement of actual products. Thereafter, as shown in FIG. 1B, a conductive layer 120 is formed on the flexible substrate 110. Specifically, a seed layer 115, for example, may be formed on the flexible substrate 110 first as shown in FIG. 1B; then, a plating process is performed by using the seed layer 115 as an electrode to form a conductive layer 120 on the flexible substrate 110 as shown in FIG. 1B. In the embodiment, the conductive layer 120 may be, for example, a copper layer. Certainly, the embodiment serves as an example only and should not be construed as a limitation to the invention.

Next, please refer to FIG. 1C; a patterning process is performed to the conductive layer 120 and the seed layer 115 as shown in FIG. 1B to form a patterned circuit layer 122 as shown in FIG. 1C on the flexible substrate 110, wherein the patterned circuit layer 122 includes a fingerprint sensing circuit 122a and a plurality of terminals 122b for electrical connection. Thereafter, a surface treatment layer 170 as shown in FIG. 1D may be formed on the patterned circuit layer 122. In the embodiment, the surface treatment layer 170 may be a gold layer, a tin layer, a nickel-gold layer, a nickel-palladium-gold layer, or an organic solderability preservative. Certainly, the embodiment serves as an example only and should not be construed as a limitation to the materials and types of the surface treatment layer 170.

Furthermore, please refer to FIG. 1E. A dielectric layer 130 is formed on the flexible substrate 110, wherein the dielectric layer 130 covers the patterned circuit layer 122 and a part of the flexible substrate 110 exposed by the patterned circuit layer 122. Thereafter, a patterning process is performed to the dielectric layer 130 to form a patterned dielectric layer 132 as shown in FIG. 1F. In the embodiment, the material of the patterned dielectric layer 132 may be, for example, polyimide, and the abovementioned patterning process may be a photolithography process. In that case, the thickness of the patterned dielectric layer 132 may be controlled by a photoresist layer formed during the photolithography process so that the patterned dielectric layer 132 having a relatively smaller thickness than the flexible substrate 110 may be formed. That is to say, the thickness of the patterned dielectric layer 132 formed through the process is substantially smaller than the thickness of the flexible substrate 110. For example, the thickness of the patterned dielectric layer 132 is substantially no more than 10 μm. More specifically, the thickness of the patterned dielectric layer 132 may substantially lies in the range of about 4 μm to 8 μm. In addition, the thickness of the patterned dielectric layer 132 formed by the photolithography process is more uniform. Apart from that, the patterned dielectric layer 132 includes a first surface 132a and a second surface 132b opposite to each other, and the patterned dielectric layer 132 at least covers the fingerprint sensing circuit 122a with the first surface 132a and exposes the terminals 122b.

Subsequently, please refer to FIG. 1G; a fingerprint sensor chip 140 is disposed on the flexible substrate 110 and electrically connected to the fingerprint sensing circuit 122a via a plurality of bumps 150. Specifically, the fingerprint sensor chip 140 includes an active surface 142, a back surface 144 and a plurality of bonding pads 146 disposed on the active surface 142. The bumps 150 are disposed between the fingerprint sensor chip 140 and the patterned circuit layer 122 to be electrically connected to the bonding pads 146 and the terminals 122b respectively so as to have the fingerprint sensor chip 140 electrically connected to the fingerprint sensing circuit 122a. In the embodiment, the method for disposing the fingerprint sensor chip 140 on the flexible substrate 110 may include, for example, a thermocompression bonding method, an ultrasonic bonding method, or a thermosonic bonding method and so on.

Then, as shown in FIG. 1H, an encapsulant layer 160 is filled between the flexible substrate 110 and the fingerprint sensor chip 140 and covers the bumps 150 as shown in FIG. 1H. In an embodiment of the invention, the encapsulant layer 160 may be an underfill. After the fingerprint sensor chip 140 is disposed on the flexible substrate 110 through, for example, a thermocompression bonding method, the encapsulant layer 160 is filled between the flexible substrate 110 and the fingerprint sensor chip 140 through, for example, a dispensing method and capillarity. In another embodiment of the invention, the encapsulant layer 160 maybe a non-conductive paste (NCP) or a non-conductive film (NCF). In the embodiment, the encapsulant layer 160 may be, for example, applied on the flexible substrate 110 first, and the fingerprint sensor chip 140 is then disposed on the flexible substrate 110 through, for example, the thermocompression bonding method so that the encapsulant layer 160 is filled between the flexible substrate 110 and the fingerprint sensor chip 140.

In another embodiment of the invention, the fingerprint sensor chip 140 may also be disposed on the flexible substrate 110 through an ultrasonic bonding method or a thermosonic bonding method. That is, in the process of bonding or thermocompression bonding the fingerprint sensor chip 140 on the flexible substrate 110, an ultrasonic vibration is applied for the bonding of the metal-metal interface. In the embodiment, the encapsulant layer 160 may be a non-conductive paste, a non-conductive film, an anisotropic conductive paste (ACP) or an anisotropic conductive film (ACF). The encapsulant layer 160 may be applied on the flexible substrate 110 first, and the fingerprint sensor chip 140 is then disposed on the flexible substrate 110 so that the encapsulant layer 160 is filled between the flexible substrate 110 and the fingerprint sensor chip 140.

Certainly, in another embodiment of the invention, the encapsulant layer 160 may also be the anisotropic conductive paste or the anisotropic conductive film. In the embodiment, the encapsulant layer 160 may be, for example, applied on the flexible substrate 110 first and then the fingerprint sensor chip 140 is directly bonded to the flexible substrate 110 by compression bonding without applying heat and/or ultrasonic vibration. In that case, the conductive particles in the anisotropic conductive paste or the anisotropic conductive film are used to have the fingerprint sensor chip 140 being electrically connected to the flexible substrate 110, and the dielectric paste of the anisotropic conductive paste or the anisotropic conductive film is used to structurally connect the fingerprint sensor chip 140 to the flexible substrate 110 and to cover the bumps 150.

With such configuration, the fabrication of a chip package structure 100 is substantially completed. As shown in FIG. 1H, the chip package structure 100 manufactured according to the abovementioned processes includes the flexible substrate 110, the patterned circuit layer 122, the fingerprint sensor chip 140, the plurality of bumps 150, the patterned dielectric layer 132 and the encapsulant layer 160, wherein the patterned circuit layer 122 is disposed on the flexible substrate 110 and includes the fingerprint sensing circuit 122a and a plurality of terminals 122b. The fingerprint sensor chip 140 is disposed on the flexible substrate 110 and electrically connected to the fingerprint sensing circuit 122a. The fingerprint sensor chip 140 includes an active surface 142, a back surface 144 and a plurality of bonding pads 146 disposed on the active surface 142. The bumps 150, as shown in FIG. 1H, are disposed between the fingerprint sensor chip 140 and the patterned circuit layer 122 to be electrically connected to the bonding pads 146 and the terminals 122b respectively.

Furthermore, the patterned dielectric layer 132 includes the first surface 132a and the second surface 132b opposite to each other, and the patterned dielectric layer 132 at least covers the fingerprint sensing circuit 122a with the first surface 132a. The second surface 132b has a fingerprint sensing region R1 as shown in FIG. 1H for receiving the user's fingerprint so that the fingerprint sensing circuit 122a generates a change in the density of electric charges and transmits a signal to the fingerprint sensor chip 140 to perform a calculation in order to identify the fingerprint. Therefore, based on the material properties of the patterned dielectric layer 132 such as dielectric constant (k), the material that facilitates the fingerprint sensing circuit 122a to sense the user's fingerprint may be selected to enhance the sensitivity of fingerprint sensing. The encapsulant layer 160 is filled between the flexible substrate 110 and the fingerprint sensor chip 140 and covers the bumps 150.

To sum up, in the invention, the photolithography process is applied to the packaging of the fingerprint sensor chip; that is, forming the patterned dielectric layer by the photolithography process to cover the fingerprint sensing circuit in order to prevent the fingerprint sensing circuit from being damaged or damped. Meanwhile, since the thickness of the patterned dielectric layer may be controlled by the photoresist layer formed during the photolithography process, the patterned dielectric layer having a thinner and more uniform thickness can be formed, thereby the thickness of the chip package structure of the invention can be reduced and the sensitivity of fingerprint identification can be enhanced. Moreover, by selecting the patterned dielectric layer according to the material properties, the sensitivity of fingerprint identification can also be enhanced.

Although the invention has been disclosed by the above embodiments, the embodiments are not intended to limit the invention. It will be apparent to those skilled in the art that various modifications and variations can be made to the structure of the invention without departing from the scope or spirit of the invention. Therefore, the protecting range of the invention falls in the appended claims.

What is claimed is:

1. A chip package structure, comprising:
a flexible substrate;
a patterned circuit layer disposed on the flexible substrate, the patterned circuit layer comprising a fingerprint sensing circuit and a plurality of terminals;
a fingerprint sensor chip disposed on the flexible substrate and electrically connected to the fingerprint sensing circuit, the fingerprint sensor chip comprising an active surface, a back surface and a plurality of bonding pads, the bonding pads being disposed on the active surface;
a plurality of bumps disposed between the fingerprint sensor chip and the patterned circuit layer to electrically connect the bonding pads with the terminals;
a patterned dielectric layer comprising a first surface and a second surface opposite to each other, the patterned dielectric layer at least covering the fingerprint sensing circuit with the first surface, the second surface having a fingerprint sensing region; and
an encapsulant layer filled between the flexible substrate and the fingerprint sensor chip and covering the bumps.

2. The chip package structure according to claim 1, wherein a thickness of the flexible substrate is greater than a thickness of the patterned dielectric layer.

3. The chip package structure according to claim 1, wherein a thickness of the patterned dielectric layer is substantially no more than 10 μm.

4. The chip package structure according to claim 1, wherein a thickness of the patterned dielectric layer substantially lies in the range of 4 μm to 8 μm.

5. The chip package structure according to claim 1, further comprising a seed layer disposed between the flexible substrate and the patterned circuit layer.

6. The chip package structure according to claim 1, wherein materials for the patterned dielectric layer and the flexible substrate comprise polyimide (PI).

7. The chip package structure according to claim 1, wherein the encapsulant layer comprises an underfill, a non-conductive paste (NCP), a non-conductive film (NCF), an anisotropic conductive paste (ACP) or an anisotropic conductive film (ACF).

8. A method for manufacturing a chip package structure, comprising:
providing a flexible substrate;
forming a conductive layer on the flexible substrate;
performing a patterning process to the conductive layer to form a patterned circuit layer on the flexible substrate, the patterned circuit layer comprises a fingerprint sensing circuit;
forming a dielectric layer on the flexible substrate, the dielectric layer covering the patterned circuit layer;
performing a patterning process to the dielectric layer to form a patterned dielectric layer, the patterned dielectric layer comprising a first surface and a second surface opposite to each other, the patterned dielectric layer at least covering the fingerprint sensing circuit with the first surface, the second surface having a fingerprint sensing region;
disposing a fingerprint sensor chip on the flexible substrate and electrically connecting the fingerprint sensor chip to the fingerprint sensing circuit via a plurality of bumps; and
filling an encapsulant layer between the flexible substrate and the fingerprint sensor chip, the encapsulant layer covering the bumps.

9. The method for manufacturing the chip package structure according to claim 8, wherein the step of forming the conductive layer on the flexible substrate further comprises:
forming a seed layer on the flexible substrate; and
performing a plating process by using the seed layer as an electrode to form the conductive layer on the flexible substrate.

10. The method for manufacturing the chip package structure according to claim 9, wherein the step of performing the patterning process to the conductive layer further comprises:
performing the patterning process to the conductive layer and the seed layer.

11. The method for manufacturing the chip package structure according to claim 8, wherein the step of performing a patterning process to the dielectric layer comprises a photolithography process.

12. The method for manufacturing the chip package structure according to claim 8, wherein the method for disposing the fingerprint sensor chip on the flexible substrate comprises a thermocompression bonding method.

13. The method for manufacturing the chip package structure according to claim 12, wherein the encapsulant layer comprises an underfill, a non-conductive paste or a non-conductive film.

14. The method for manufacturing the chip package structure according to claim 8, wherein the step of disposing the fingerprint sensor chip on the flexible substrate comprises compression bonding the fingerprint sensor chip to the flexible substrate and applying an ultrasonic vibration during the bonding process.

15. The method for manufacturing the chip package structure according to claim 14, wherein the encapsulant layer comprises a non-conductive paste, a non-conductive film, an anisotropic conductive paste or an anisotropic conductive film.

16. The method for manufacturing the chip package structure according to claim 8, wherein the encapsulant layer comprises an anisotropic conductive paste or an anisotropic conductive film.
